(19) United States
(12) Patent Application Publication
(10) Pub. No.: US 2025/0338682 A1
(43) Pub. Date: Oct. 30, 2025

(54) LANDING PAD STRUCTURES FOR CONTACTS IN LIGHT-EMITTING DIODE CHIPS AND RELATED METHODS

(71) Applicant: CreeLED, Inc., Durham, NC (US)

(72) Inventors: Steven Wuester, Wake Forest, NC (US); Michael Check, Holly Springs, NC (US); Andre Pertuit, Raleigh, NC (US); Daniel Carleton Driscoll, Cary, NC (US)

(21) Appl. No.: 18/645,598

(22) Filed: Apr. 25, 2024

(51) Int. Cl. H01L 33/62; H01L 33/00; H01L 33/22; H01L 33/46

(52) U.S. Cl. CPC H10H 20/857; H10H 20/0137; H10H 20/82; H10H 20/841

(57) ABSTRACT

Solid-state lighting devices including light-emitting diodes (LEDs) and more particularly landing pad structures in LED chips and related methods are disclosed. Landing pad structures include landing pads for contacts positioned outside active LED structures of LED chips. Landing pads and metal reflective layers form portions of electrically conductive pathways between contacts and active LED structures. Dielectric reflective layers and metal reflective layers may form reflective structures proximate active LED structures, while also extending outside active LED structures proximate landing pads. Landing pads may extend through openings of dielectric reflective layers to form electrical connections with metal reflective layers. As described herein, landing pad structures allow increased thickness of metal reflective layers to reduce topography variations, increase current handling, and/or increase reflectivity in LED chips.

### FIELD OF THE DISCLOSURE

The present disclosure relates to solid-state lighting devices including light-emitting diodes (LEDs) and more particularly to landing pad structures in LED chips and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into active layers and corresponding recombination generates emissions of light. An active region may be fabricated, for example, from gallium nitride, gallium phosphide, aluminum nitride, and/or gallium arsenide-based materials and/or from organic semiconductor materials.

As advancements in modern LED technology progress, the art continues to seek improved LEDs and solid-state lighting devices having desirable illumination characteristics capable of overcoming challenges associated with conventional devices.

### SUMMARY

The present disclosure relates to solid-state lighting devices including light-emitting diodes (LEDs) and more particularly to landing pad structures in LED chips and related methods. Landing pad structures include landing pads for contacts positioned outside active LED structures of LED chips. Landing pads and metal reflective layers form portions of electrically conductive pathways between contacts and active LED structures. Dielectric reflective layers and metal reflective layers may form reflective structures proximate active LED structures, while also extending outside active LED structures proximate landing pads. Landing pads may be positioned to extend through openings of dielectric reflective layers to form electrical connections with metal reflective layers. As described herein, landing pad structures allow increased thickness of metal reflective layers to reduce topography variations, increase current handling, and/or increase reflectivity in LED chips.

In one aspect, an LED chip comprises: a carrier submount; an active LED structure on the carrier submount, the active LED structure comprising an n-type layer, a p-type layer, and an active layer between the n-type layer and the p-type layer, the active LED structure forming sidewalls that define a perimeter of the active LED structure; a metal reflective layer between the active LED structure and the carrier submount, a portion of the metal reflective layer extending outside the sidewalls; a contact on the carrier submount in a position that is outside the sidewalls; and a landing pad between the contact and the metal reflective layer, the landing pad electrically coupling the contact to the metal reflective layer outside the sidewalls. In certain embodiments, at least a portion of the landing pad is between the contact and the metal reflective layer in a direction perpendicular to the carrier submount. In certain embodiments, the metal reflective layer is electrically coupled to the active LED structure.

The LED chip may further comprise a dielectric reflective layer on the active LED structure, wherein one or more portions of the metal reflective layer extend through the dielectric reflective layer to electrically couple the metal reflective layer to the active LED structure. In certain embodiments, the dielectric reflective layer extends outside the sidewalls, and the landing pad extends through the dielectric reflective layer to electrically couple the landing pad to the contact. In certain embodiments, a portion of the landing pad laterally extends on the dielectric reflective layer in a position that is between the dielectric reflective layer and the metal reflective layer. The LED chip may further comprise an adhesion layer between the dielectric reflective layer and the metal reflective layer, and the portion of the landing pad laterally extends on the adhesion layer in a position that is between the adhesion layer and the metal reflective layer.

In certain embodiments, the metal reflective layer comprises a thickness in a range from 0.2 microns (μm) to 1.5 μm.

In certain embodiments, the LED chip may further comprise a passivation layer between the metal reflective layer and the carrier submount. In certain embodiments, the LED chip may further comprise one or more top passivation layers on the sidewalls of the active LED structure and on one or more portions of the contact. In certain embodiments, the one or more top passivation layers further contact a portion of the landing pad. In certain embodiments, the LED chip may further comprise a dielectric reflective layer on the active LED structure, wherein one or more portions of the metal reflective layer extend through the dielectric reflective layer to electrically couple the metal reflective layer to the active LED structure, wherein a portion of the dielectric reflective layer extends outside the sidewalls to contact the landing pad. In certain embodiments, the one or more top passivation layers contact a portion of the dielectric reflective layer between the sidewalls and the landing pad.

In another aspect, a method of forming an LED chip comprises: forming an active LED structure, the active LED structure comprising an n-type layer, a p-type layer, and an active layer between the n-type layer and the p-type layer, the active LED structure forming sidewalls that define a perimeter of the active LED structure; depositing a dielectric reflective layer on the active LED structure, a portion of the dielectric reflective layer extending outside the sidewalls; removing portions of the dielectric reflective layer to form a first opening in the dielectric reflective layer outside the sidewalls; depositing a landing pad in the first opening; depositing a metal reflective layer on the dielectric reflective layer and the landing pad such that the landing pad is electrically coupled to the metal reflective layer outside the sidewalls; bonding the active LED structure to a carrier submount such that the metal reflective layer is between the active LED structure and the carrier submount; and forming a contact on the landing pad such that the landing pad is between the contact and the metal reflective layer. The method may further comprise removing portions of the dielectric reflective layer to form a plurality of second openings over the active LED structure. In certain embodiments, depositing the metal reflective layer further comprises filling the plurality of second openings with the metal reflective layer to form electrically conductive pathways to the active LED structure. In certain embodiments, at least a portion of the landing pad is between the contact and the metal reflective layer in a direction perpendicular to the carrier submount. In certain embodiments, a portion of the landing pad laterally extends on the dielectric reflective layer in a position that is between the dielectric reflective layer and the metal reflective layer. The method may further comprise forming one or more top passivation layers on the sidewalls of the active LED structure, on one or more portions of the contact, and on portions of the dielectric reflective layer between the sidewalls and the landing pad. In certain embodiments, the metal reflective layer comprises a thickness in a range from 0.2 microns (μm) to 1.5 μm.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a generalized cross-section of an LED chip that includes landing pad structures according to principles of the present disclosure.

FIG. 2A is a generalized cross-section of the LED chip of FIG. 1 at an initial fabrication step for forming the landing pad structure according to principles of the present disclosure.

FIG. 2B is a generalized cross-section of the LED chip of FIG. 2A at a subsequent fabrication step after formation of a first reflective layer and an adhesion layer.

FIG. 2C is a generalized cross-section of the LED chip of FIG. 2B at a subsequent fabrication step after various openings are formed through the first reflective layer and the adhesion layer.

FIG. 2D is a generalized cross-section of the LED chip of FIG. 2C at a subsequent fabrication step after a landing pad is formed in a first opening.

FIG. 2E is a generalized cross-section of the LED chip of FIG. 2D at a subsequent fabrication step after a second reflective layer is formed on the landing pad and over portions of the first reflective layer and/or adhesion layer.

FIG. 2F is a generalized cross-section of the LED chip of FIG. 2E at a subsequent fabrication step after formation of a passivation layer.

FIG. 2G is a generalized cross-section of the LED chip of FIG. 2F at a subsequent fabrication step after the formation of an n-contact metal layer and bonding of a carrier submount by way of a bond metal layer.

FIG. 2H is a generalized cross-section of the LED chip of FIG. 2G at a subsequent fabrication step after a growth substrate of the LED chip of FIG. 2F is removed.

FIG. 2I is a generalized cross-section of the LED chip of FIG. 2H at a subsequent fabrication step after portions of the active LED structure over the landing pad are removed.

FIG. 2J is a generalized cross-section of the LED chip of FIG. 2I at a subsequent fabrication step after a p-contact and top passivation layers are formed to provide the LED chip of FIG. 1

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to landing pad structures in LED chips and related methods. Landing pad structures include landing pads for contacts positioned outside active LED structures of LED chips. Landing pads and metal reflective layers form portions of electrically conductive pathways between contacts and active LED structures. Dielectric reflective layers and metal reflective layers may form reflective structures proximate active LED structures, while also extending outside active LED structures proximate landing pads. Landing pads may be positioned to extend through openings of dielectric reflective layers to form electrical connections with metal reflective layers. As described herein, landing pad structures allow increased thickness of metal reflective layers to reduce topography variations, increase current handling, and/or increase reflectivity in LED chips.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group Ill nitrides refer to those semiconductor compounds formed between nitrogen (N) and the elements in Group Ill of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations.

Light emitted by the active layer or region of an LED chip typically is initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

For LED chips with an active LED structure bonded to a carrier submount, bond metal layers are typically employed to facilitate bonding. During typical bonding processes, such as eutectic bonding, bonding conditions such as temperature, bonding pressure, and cooling rates are controlled to provide adequate bonding strength. When LED chips have substantial differences in topography above the carrier submount, voiding of the bonding materials may occur and cause localized bonding strength to be reduced. In this regard, electrically conductive pathways to the active LED structure that are routed between the active LED structure and the carrier submount have certain thickness limitations to avoid creating adverse topology differences.

According to aspects of the present disclosure, landing pad structures are disclosed that provide landing locations for electrical contacts adjacent active LED structures. By positioning a landing pad structure outside a mesa region of an active LED structure, the relative thickness of the landing pad structure may be controlled such that topology differences between the active LED structure and corresponding carrier submount are reduced. Additionally, the thickness of the landing pad structure may further allow increased thickness for electrically conductive layers that route between the active LED structure and the carrier submount, thereby allowing increased current handling. Landing pad structures may include a landing pad positioned to make an electrical connection with a topside contact adjacent the active LED structure. As used herein, a landing pad may comprise one or more electrically conductive metal layers, including but not limited to titanium (Ti), platinum (Pt), nickel (Ni), gold (Au), tungsten (W), chromium (Cr) and combinations or alloys thereof. In certain embodiments, certain metals may be positioned as an etch stop during formation of the contact and other metals may serve to reduce migration of other metals toward the contact.

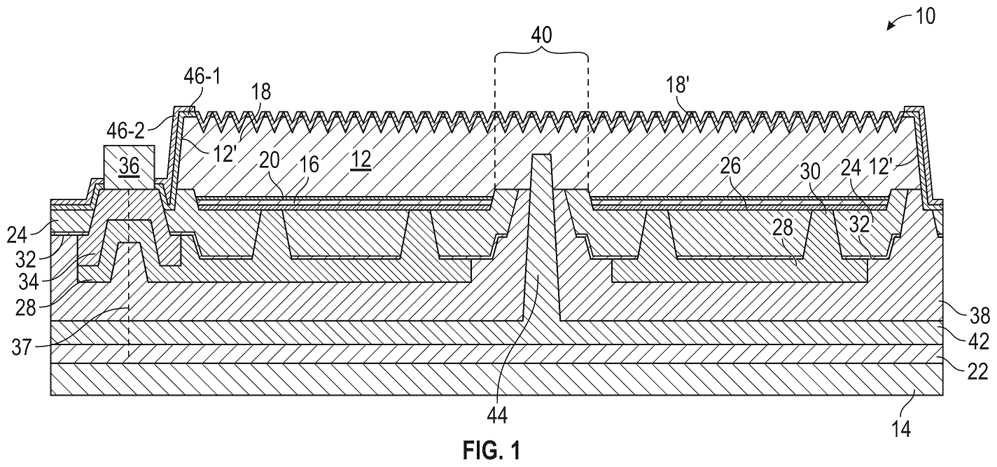

FIG. 1 is a generalized cross-section of an LED chip 10 that includes landing pad structures according to principles of the present disclosure. The LED chip 10 includes an active LED structure 12 formed on a carrier submount 14. The active LED structure 12 generally refers to portions of the LED chip 10 that include semiconductor layers, such as epitaxial semiconductor layers, that form a structure that generates light when electrically activated. The active LED structure 12 is formed on and supported by the carrier submount 14 that can be made of many different materials, with a suitable material being silicon or doped silicon. In certain embodiments, the carrier submount 14 comprises an electrically conductive material such that the carrier submount 14 is part of electrically conductive connections to the active LED structure 12. The active LED structure 12 may generally comprise a p-type layer 16, an n-type layer 18, and an active layer 20 arranged between the p-type layer 16 and the n-type layer 18. The active LED structure 12 may include many additional layers such as, but not limited to, buffer layers, nucleation layers, super lattice structures, undoped layers, cladding layers, contact layers, current-spreading layers, and light extraction layers and elements. In various embodiments, the active layer 20 may comprise a single quantum well, a multiple quantum well, a double heterostructure, or super lattice structures. In FIG. 1, the p-type layer 16 is arranged between the active layer 20 and the carrier submount 14 such that the p-type layer 16 is closer to the carrier submount 14 than the n-type layer 18. The active LED structure 12 may initially be formed by epitaxially growing or depositing the n-type layer 18, the active layer 20, and the p-type layer 16 sequentially on a growth substrate. The active LED structure 12 may then be flipped and bonded to the carrier submount 14 by way of one or more bond metal layers 22 and the growth substrate is removed. In this manner, a top surface 18′ of the n-type layer 18 forms a primary light-extracting face of the LED chip 10. In certain embodiments, the top surface 18′ may comprise a textured or patterned surface for improving light extraction. In other embodiments, the doping order may be reversed such that the n-type layer 18 is arranged between the active layer 20 and the carrier submount 14.

The LED chip 10 may include a first reflective layer 24 provided on the p-type layer 16. In certain embodiments, a current spreading layer 26 may be provided between the p-type layer 16 and the first reflective layer 24. The current spreading layer 26 may include a thin layer of a transparent conductive oxide such as indium tin oxide (ITO) or a thin metal layer such as Pt, although other materials may be used. The first reflective layer 24 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the first reflective layer 24 comprises a material with an index of refraction lower than the index of refraction of the active LED structure 12 material. The first reflective layer 24 may comprise many different materials, with some having an index of refraction less than 2.3, while others can have an index of refraction less than 2.15, less than 2.0, and less than 1.5. In certain embodiments, the first reflective layer 24 comprises a dielectric material, such as silicon dioxide (SiO₂) and/or silicon nitride (SiN). It is understood that many dielectric materials can be used such as SiN, SiNₓ, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In certain embodiments, the first reflective layer 24 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the first reflective layer 24 comprising SiO₂ may form a sufficient index of refraction step between the two to allow for efficient TIR of light. The first reflective layer 24 may have different thicknesses depending on the type of materials used, with some embodiments having a thickness of at least 0.2 microns (μm). In some embodiments, the first reflective layer 24 can have a thickness in the range of 0.2 μm to 0.7 μm, while in some embodiments the thickness can be approximately 0.5 μm. As used herein, the first reflective layer 24 may also be referred to as a dielectric reflective layer and the terms may be used interchangeably.

The LED chip 10 may further include a second reflective layer 28 that is on the first reflective layer 24 such that the first reflective layer 24 is arranged between the active LED structure 12 and the second reflective layer 28. The second reflective layer 28 may include a metal layer that is configured to reflect light from the active LED structure 12 that may pass through the first reflective layer 24. As used herein, the second reflective layer 28 may also be referred to as a metal reflective layer and the terms may be used interchangeably. The second reflective layer 28 may comprise many different materials such as Ag, gold (Au), Al, nickel (Ni), titanium (Ti), or combinations thereof. The second reflective layer 28 may have different thicknesses depending on the type of materials used, with some embodiments having a thickness of at least 0.1 μm, or in a range from 0.1 μm to 0.7 μm, or in a range from 0.1 μm to 0.5 um, or in a range from 0.1 μm to 0.3 μm. As described in more detail below, certain embodiments allow increased thickness of the second reflective layer 28, such as ranges up to about 1.5 μm. As illustrated, the second reflective layer 28 may include or form one or more reflective layer interconnects 30 that provide an electrically conductive path through the first reflective layer 24. In this manner, the one or more reflective layer interconnects 30 may extend through an entire thickness of the first reflective layer 24. In certain embodiments, the second reflective layer 28 is a metal reflective layer and the reflective layer interconnects 30 comprise reflective layer metal vias.

Accordingly, the first reflective layer 24, the second reflective layer 28, and the reflective layer interconnects 30 form a reflective structure of the LED chip 10 that is on the p-type layer 16. As such, the reflective structure may comprise a dielectric reflective layer and a metal reflective layer as disclosed herein. In certain embodiments, the reflective layer interconnects 30 comprise the same material as the second reflective layer 28 and are formed at the same time as the second reflective layer 28. In other embodiments, the reflective layer interconnects 30 may comprise a different material than the second reflective layer 28. Certain embodiments may also comprise an adhesion layer 32 that is positioned at one or more interfaces between the first reflective layer 24 and the second reflective layer 28 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlxOy. In certain embodiments, the adhesion layer comprises AlₓO_{y}, where 1≤x≤4 and 1≤y≤6. In certain embodiments, the adhesion layer comprises AlₓO_{y}, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD). In still further embodiments, the adhesion layer 32 may comprise a discontinuous layer.

According to aspects of the present disclosure, the LED chip 10 includes a landing pad 34 is positioned laterally adjacent the active LED structure 12. The landing pad 34 is positioned to provide an electrical connection with a p-contact 36. The p-contact 36, which may also be referred to as a bond pad, may provide a surface to receive an external electrical connection, for example by way of a wire bond. In other embodiments, the polarity may be reversed such that the p-contact 36 is replaced with an n-contact that is electrically coupled to the n-type layer 18, and electrical connections to the p-type layer 16 are made through the carrier submount 14. As illustrated, a lateral extension of the second reflective layer 28 is electrically coupled to the landing pad 34. In certain embodiments, the second reflective layer 28 is electrically connected to a side of the landing pad 34 that is oriented toward the carrier submount 14 such that portions of the second reflective layer 28 are between the landing pad 34 and the carrier submount 14. In certain embodiments, at least a portion of the landing pad 34 is positioned between the p-contact 36 and the second reflective layer 28 in a direction 37 perpendicular to the carrier submount 14. In such arrangements, the landing pad 34 forms part of an electrically conductive path between the p-contact 36 and the p-type layer 16 that includes the landing pad 34, the second reflective layer 28, and the reflective layer interconnects 30. As illustrated, the first reflective layer 24 extends outside sidewalls 12′ of the active LED structure 12, and the landing pad 34 may extend through the first reflective layer 24 to electrically couple the landing pad 34 to the p-contact 36. Additionally, a portion of the landing pad 34 may laterally extend on the first reflective layer 24 in a position that is between the first reflective layer 24 and the second reflective layer 28.

A passivation layer 38 is included on the second reflective layer 28 in a position that is between the second reflective layer 28 and the carrier submount 14. The passivation layer 38 protects and provides electrical insulation for the LED chip 10 and can comprise many different materials, such as a dielectric material including but not limited to silicon nitride. In certain embodiments, the passivation layer 38 is a single layer, and in other embodiments, the passivation layer 38 comprises a plurality of layers. In certain embodiments, the passivation layer 38 may include one or more metal-containing interlayers arranged or embedded therein that may function as a crack stop layer for any cracks that may propagate through the passivation layer 38 as well as an additional light reflective layer.

In FIG. 1, the active LED structure 12 forms a first recess 40, or opening, that extends through the p-type layer 16, the active layer 20, and a portion of the n-type layer 18. The first recess 40 may be formed by a subtractive material process, such as etching, that is applied to the active LED structure 12 before bonding with the carrier submount 14. As used herein, the first opening 40 may also be referred to as an active LED structure opening. As illustrated, a portion of the first reflective layer 24 is arranged to cover sidewall surfaces of the p-type layer 16, the active layer 20, and the n-type layer 18 within the first recess 40. The passivation layer 38 extends along the first reflective layer 24 in the first recess 40 and is arranged on a surface of the n-type layer 18. The LED chip 10 further includes an n-contact metal layer 42 that is arranged on the passivation layer 38 and across the LED chip 10. At the first recess 40, the n-contact metal layer 42 extends into the first recess 40 to form an n-contact interconnect 44, which may be referred to as an n-contact via. In this manner, the first recess 40 may be defined where portions of the n-contact metal layer 42, the n-contact interconnect 44, the passivation layer 38, and the first reflective layer 24 extend into the active LED structure 12. As such, the n-contact metal layer 42 and the n-contact interconnect 44 may be integrally formed to provide an electrical connection to the n-type layer 18 through the first recess 40. In other embodiments, the n-contact metal layer 42 and the n-contact interconnect 44 may be separately formed and may comprise the same or different materials. In certain embodiments, the n-contact metal layer 42 and the n-contact interconnect 44 comprise a single layer or a plurality of layers that include conductive metals, such as one or more of Al, Ti, and alloys thereof.

As illustrated, the p-contact 36 may be formed on the landing pad 34, and one or more top passivation layers 46-1, 46-2 may be provided on one or more top or side surfaces of the n-type layer 18 for additional electrical insulation. The top passivation layers 46-1, 46-2 may comprise separate layers of a continuous layer of dielectric material, such as silicon nitride. In FIG. 1, the top passivation layers 46-1, 46-2 are arranged to cover sidewalls 12′ of the active LED structure 12. The top passivation layers 46-1, 46-2 may further contact portions of the first reflective layer 24 between the sidewalls 12′ and the landing pad 34 to effectively seal the active LED structure 12. As illustrated, the passivation layers 46-1, 46-2 may further cover portions of the landing pad 34 that are adjacent the p-contact 36 for further sealing.

As mentioned above, the active LED structure 12 is bonded to the carrier submount 14 by way of one or more of the bond metal layers 22. Exemplary bond metal layers 22 may include Au, tin (Sn), Ni, palladium (Pd), Ti, W, and alloys thereof. During bonding, such as a eutectic bonding process, the bond metal layers 22 are heated to collectively form bonding materials (e.g., one or more eutectic alloys) between the active LED structure 12 and the carrier submount 14. By positioning the landing pad 34 vertically between the p-contact 36 and the second reflective layer 28, the second reflective layer 28 may be formed with an increased thickness between the active LED structure 12 and the carrier submount 14. Since a lateral extension of the second reflective layer 28 effectively covers a bottom side of the landing pad 34, the thickness of the second reflective layer 28 may be increased without significant impact on the bonding topology. With increased thickness, the second reflective layer 28 may facilitate increased current handling and/or increased reflectivity during operation for increased light output. Additionally, the lateral extension of the second reflective layer 28 beneath the p-contact 36 may provide increased surface area of the second reflective layer 28 for further increased light output. In certain embodiments, a thickness of the second reflective layer 28 between the first reflective layer 24 and the passivation layer 38 may be increased to higher portions or even above the previously described thickness ranges, such as is in a range from 0.2 μm to 1.5 μm, or in a range from 0.5 μm to 1.5 μm, or in a range from 0.6 μm to 1.5 μm, or in a range from 0.7 μm to 1.5 μm. However, the principles described above are also applicable to thinner thickness values of the second reflective layer 28, such as at least 0.1 μm, or in a range from 0.1 μm to 0.7 μm, or in a range from 0.1 μm to 0.5 μm, or in a range from 0.1 μm to 0.3 μm as previously described.

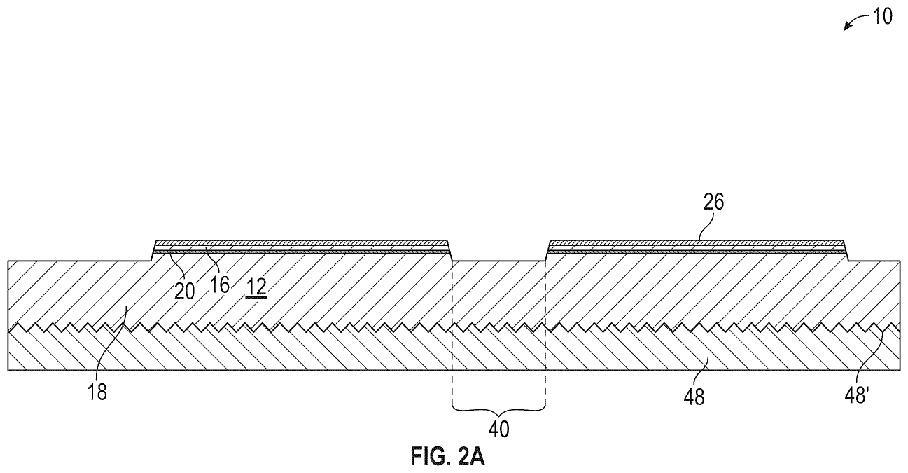

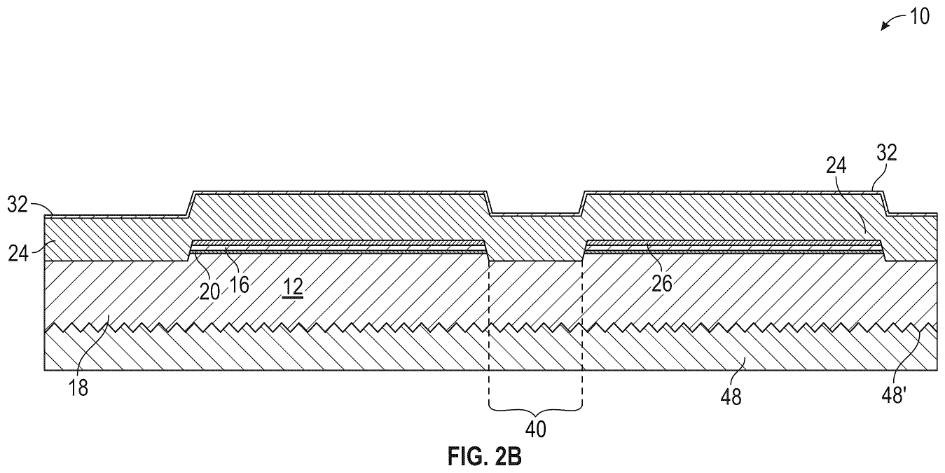

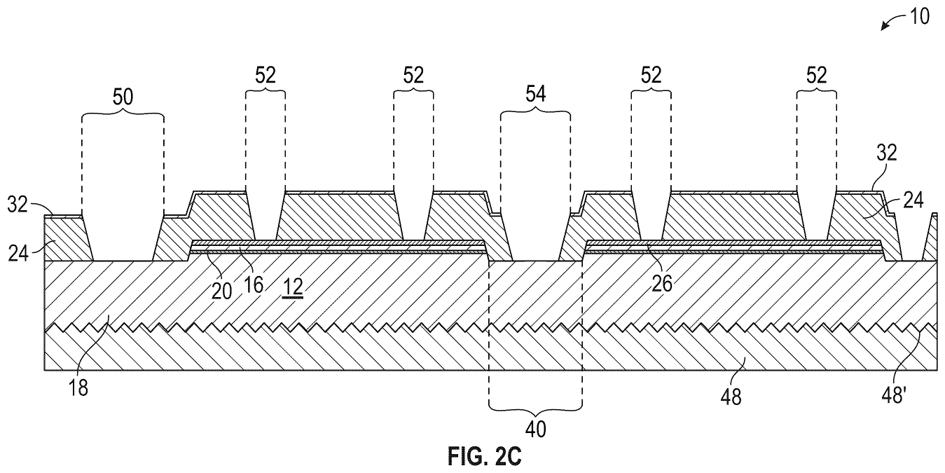

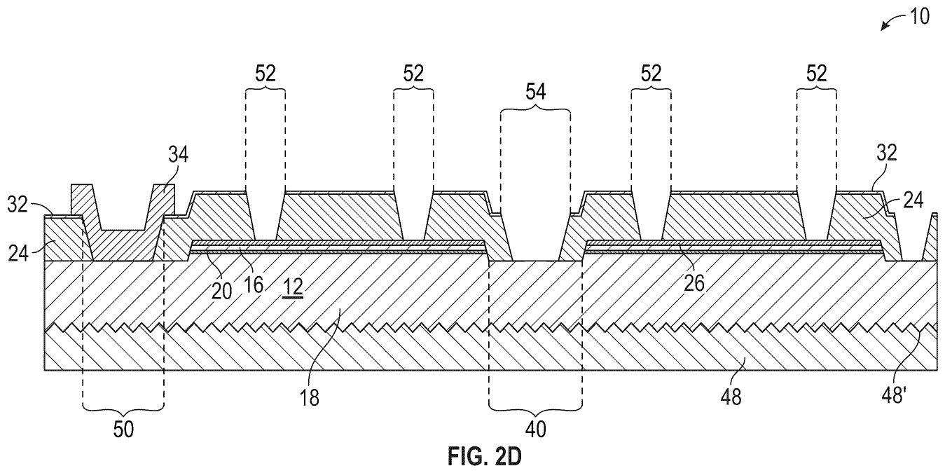

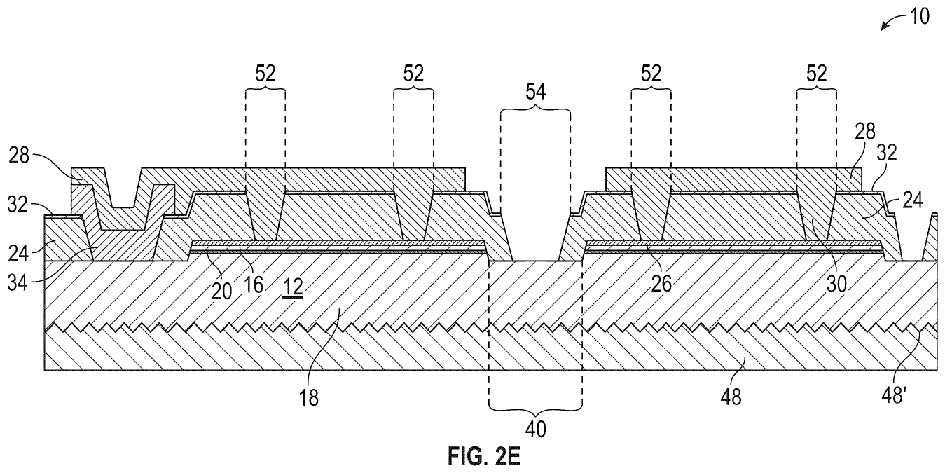

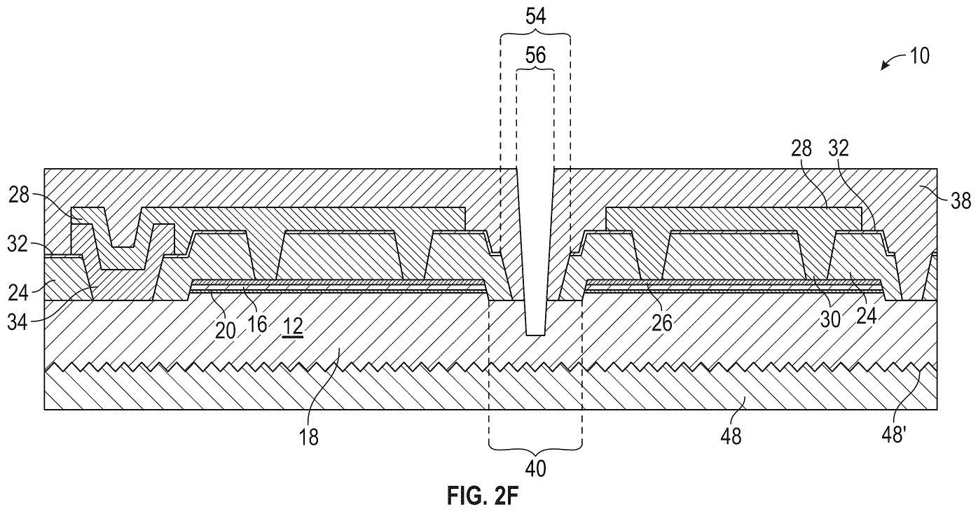

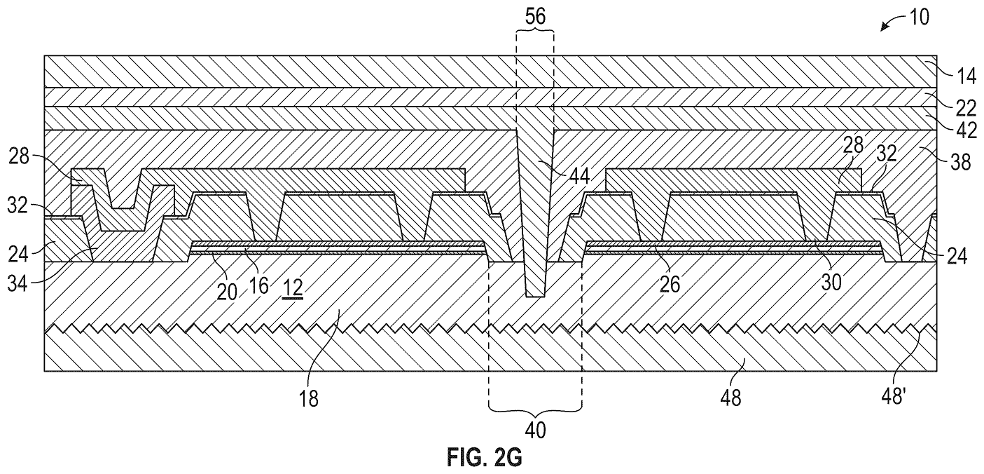

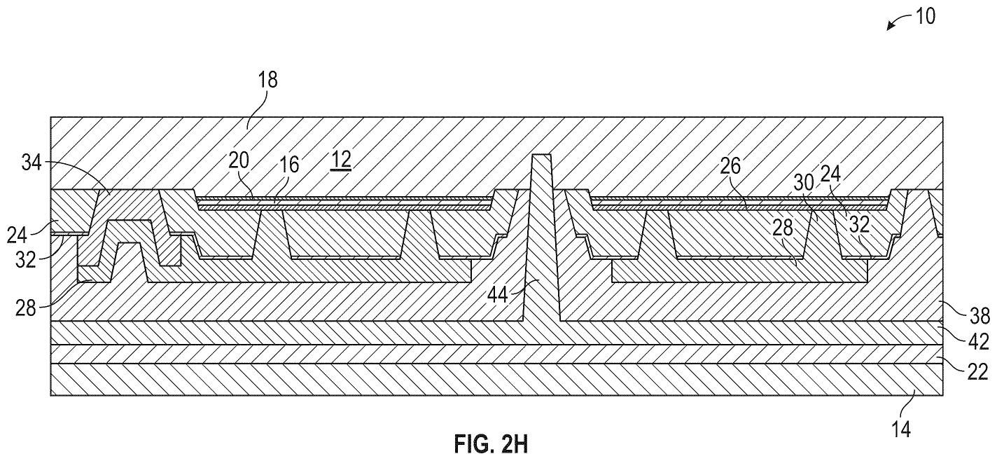

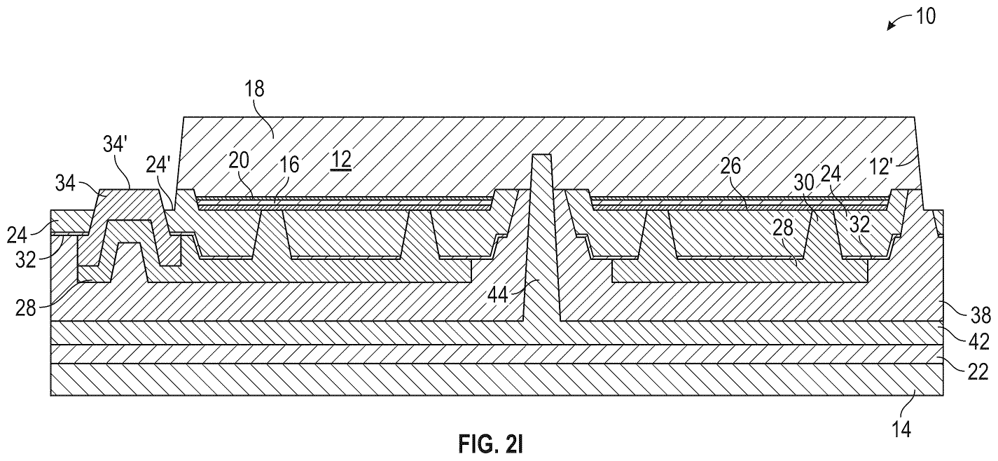

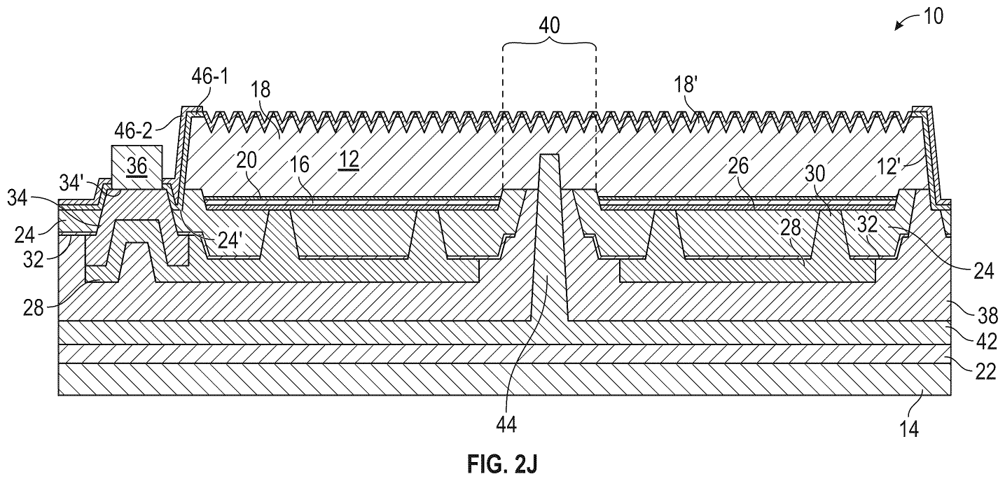

FIGS. 2A to 2J illustrate the LED chip 10 of FIG. 1 at various fabrication steps for forming the landing pad structure according to principles of the present disclosure. FIGS. 2A to 2J represent various cross-sections from the perspective of the LED chip 10; however, it is understood the fabrication steps may be performed at a wafer level so that a plurality of the LED chips 10 are formed in bulk before singulation to arrive at the LED chip 10 of FIG. 1.

FIG. 2A is a generalized cross-section of the LED chip 10 of FIG. 1 at a fabrication step after the active LED structure 12 is formed on a growth substrate 48. In certain embodiments, the active LED structure 12 may be epitaxially grown on the growth substrate 48. By way of example, the growth substrate 48 may embody a sapphire substrate. In still further examples, the growth substrate 48 may embody a patterned sapphire substrate with patterned features 48′. After growth, portions of the active LED structure 12 may be subjected to a subtractive process, such as etching to form the first recess 40 as well as a mesa that includes the current spreading layer 26, the p-type layer 16, the active layer 20, and a portion of the n-type layer 18. A single first recess 40 is shown for illustrative purposes. In certain embodiments, a plurality of the first recesses 40 may be formed in an array across the active LED structure 12.

FIG. 2B is a generalized cross-section of the LED chip 10 of FIG. 2A at a subsequent fabrication step after formation of the first reflective layer 24 and the adhesion layer 32. The first reflective layer 24 may comprise a single dielectric layer or a plurality of dielectric layers as described above. As illustrated, the first reflective layer and the adhesion layer 32 may be blanket deposited over the active LED structure 12, following the topology of the first recess 40 and the mesas. In certain embodiments, the adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD). In still further embodiments, the adhesion layer 32 may comprise a discontinuous layer.

FIG. 2C is a generalized cross-section of the LED chip 10 of FIG. 2B at a subsequent fabrication step after various openings are formed through the first reflective layer 24 and the adhesion layer 32. The various openings include a first opening 50, second openings 52, and one or more third openings 54 that may be formed by a subtractive process, such as etching. The first opening 50 corresponds to a location of the landing pad 34 of FIG. 1, the second openings correspond with locations of the reflective layer interconnects 30 of FIG. 1, and the one or more third openings 54 correspond with locations of the n-contact interconnect 44 of FIG. 1.

FIG. 2D is a generalized cross-section of the LED chip 10 of FIG. 2C at a subsequent fabrication step after the landing pad 34 is formed in the first opening 50. As illustrated, the landing pad 34 may be deposited to generally fill the first opening 50 through an entire thickness of the first reflective layer 24. In certain embodiments, one or more portions of the landing pad 34 are formed to laterally extend over portions of the first reflective layer 24 and/or the adhesion layer 32, thereby ensuring full coverage of the first opening 50. As further illustrated, a thickness of the landing pad 34 may account for certain topography differences at or near the first opening 50 and outside the mesa of the active LED structure 12.

FIG. 2E is a generalized cross-section of the LED chip 10 of FIG. 2D at a subsequent fabrication step after the second reflective layer 28 is formed on the landing pad 34 and over portions of the first reflective layer 24 and/or adhesion layer 32. As illustrated, the second reflective layer 28 is deposited to fill the second openings 52, thereby forming electrically conductive paths through the first reflective layer 24 to the active LED structure 12. In certain embodiments, the second reflective layer 28 is formed with a thickness sufficient to reduce topology variations along the LED chip 10. As described above, the increased thickness of the second reflective layer 28 may further increase current handling and/or reflectivity, thereby increasing light output.

FIG. 2F is a generalized cross-section of the LED chip 10 of FIG. 2E at a subsequent fabrication step after formation of the passivation layer 38. As illustrated, the passivation layer 38 may be blanket deposited over the LED chip 10, followed by removing a portion of the passivation layer 38 to form a fourth opening 56 that is registered with the third opening 54. As illustrated, portions of the passivation layer 38 extend through the third opening 54, thereby providing sidewall passivation to the n-type layer 18. The fourth opening 56 corresponds with a precise location for the n-contact interconnect 44 of FIG. 1.

FIG. 2G is a generalized cross-section of the LED chip 10 of FIG. 2F at a subsequent fabrication step after the formation of the n-contact metal layer 42 and bonding of the carrier submount 14 by way of the bond metal layer 22. In certain embodiments, the n-contact metal layer 42 is deposited across the passivation layer 38 and within the fourth opening 56 to form the n-contact interconnect 44.

FIG. 2H is a generalized cross-section of the LED chip 10 of FIG. 2G at a subsequent fabrication step after the growth substrate 48 of FIG. 2F is removed. As illustrated, the LED chip 10 may then be flipped such that the active LED structure 12 is oriented up for further processing.

FIG. 2I is a generalized cross-section of the LED chip 10 of FIG. 2H at a subsequent fabrication step after portions of the active LED structure 12 over the landing pad 34 are removed, thereby exposing a surface of the landing pad 34. The portions of the active LED structure 12 may be removed by an etching process that forms a recessed surface 24′ of the first reflective layer 24 proximate the landing pad 34. In certain embodiments, a metal sublayer of the landing pad 34 at or near a top surface 34′ of the landing pad 34 as oriented in FIG. 2I is formed of a metal, such as Pt and/or Cr, that provides an etch stop. The remainder of the landing pad 34 may include one or more other metal sublayers with materials, such as Ni and/or Ti, that resist migration of metals from the second reflective layer 28 from reaching the p-contact 36 of FIG. 2J.

FIG. 2J is a generalized cross-section of the LED chip 10 of FIG. 2I at a subsequent fabrication step after the p-contact 36 and the top passivation layers 46-1, 46-2 are formed. In certain embodiments the top surface 18′ of the n-type layer 18 may be textured or patterned before formation of the top passivation layers 46-1, 46-2. The p-contact 36 may be deposited on the top surface 34′ of the landing pad 34. In certain embodiments, the top passivation layers 46-1, 46-2 may first be blanket deposited over the landing pad 34 to effectively form passivation sealing with the first reflective layer 24 and/or the recessed surface 24′ of the first reflective layer. Portions of the top passivation layers 46-1, 46-2 over the landing pad 34 may then be removed and the p-contact 36 may then be formed to contact the top surface 34′ of the landing pad 34. In this manner the view of the LED chip 10 of FIG. 2J may be the same as the LED chip 10 as illustrated in FIG. 1.

The fabrication sequence illustrated in FIGS. 2A to 2J provides a number of technical improvements related to formation of the landing pad 34. As described above, the arrangement of the landing pad 34 relative to the second reflective layer 28 allows for reduced topography differences for enhanced bonding integrity to the carrier submount 14. The second reflective layer 28 may also be formed with increased thickness, thereby providing increased reflectivity and/or current handling. Other technical improvements may relate to forming the landing pad 34 early enough in the fabrication sequence to reduce the number of etching steps. For example, the side of the first reflective layer 24 and/or the adhesion layer 32 closest to the second reflective layer 28 may only be subjected to a single etch step as illustrated in FIG. 2C. At FIG. 2C, the first opening 50 has been formed concurrently with the second openings 52 and the one or more third openings 54. In this manner, the landing pad 34 is formed in the first opening 50 through an entire thickness of the first reflective layer 24, and the top surface 34′ of the pre-formed landing pad 34 only needs to be exposed at FIG. 2I for receiving the p-contact 36 of FIG. 2J. By not having to etch through an entirety of the first reflective layer 24 at FIG. 2I to form an electrically conductive path to the second reflective layer 28, additional etchants are not exposed to underlying interfaces or sidewalls of the first reflective layer 24 and/or the adhesion layer 32. In this manner, resist-related erosion of such layers may be avoided. Additionally, a reduction in resist reticulation and/or photopolymer by-product may be realized. Photopolymer build-up may otherwise occur along sidewalls of etched features, creating potentially deleterious effects related to light absorption of photopolymers and/or off-gassing of photopolymers during thermal cycling. Further advantages involve the ability to create hermetic sealing near the p-contact 36. As illustrated in FIG. 2J, the top passivation layers 46-1, 46-2 may seal portions of the landing pad 34, the p-contact 36, the active LED structure 12, and portions of the first reflective layer 24. This arrangement may provide suitable spacing between the adhesion layer 32 and the top passivation layers 46-1, 46-2 to maintain sealing integrity.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
a carrier submount;
an active LED structure on the carrier submount, the active LED structure comprising an n-type layer, a p-type layer, and an active layer between the n-type layer and the p-type layer, the active LED structure forming sidewalls that define a perimeter of the active LED structure;
a metal reflective layer between the active LED structure and the carrier submount, a portion of the metal reflective layer extending outside the sidewalls;
a contact on the carrier submount in a position that is outside the sidewalls; and
a landing pad between the contact and the metal reflective layer, the landing pad electrically coupling the contact to the metal reflective layer outside the sidewalls.

2. The LED chip of claim 1, wherein at least a portion of the landing pad is between the contact and the metal reflective layer in a direction perpendicular to the carrier submount.

3. The LED chip of claim 1, wherein the metal reflective layer is electrically coupled to the active LED structure.

4. The LED chip of claim 3, further comprising a dielectric reflective layer on the active LED structure, wherein one or more portions of the metal reflective layer extend through the dielectric reflective layer to electrically couple the metal reflective layer to the active LED structure.

5. The LED chip of claim 4, wherein the dielectric reflective layer extends outside the sidewalls, and the landing pad extends through the dielectric reflective layer to electrically couple the landing pad to the contact.

6. The LED chip of claim 5, wherein a portion of the landing pad laterally extends on the dielectric reflective layer in a position that is between the dielectric reflective layer and the metal reflective layer.

7. The LED chip of claim 6, further comprising an adhesion layer between the dielectric reflective layer and the metal reflective layer, and the portion of the landing pad laterally extends on the adhesion layer in a position that is between the adhesion layer and the metal reflective layer.

8. The LED chip of claim 1, wherein the metal reflective layer comprises a thickness in a range from 0.2 microns (μm) to 1.5 μm.

9. The LED chip of claim 1, further comprising a passivation layer between the metal reflective layer and the carrier submount.

10. The LED chip of claim 1, further comprising one or more top passivation layers on the sidewalls of the active LED structure and on one or more portions of the contact.

11. The LED chip of claim 10, wherein the one or more top passivation layers further contact a portion of the landing pad.

12. The LED chip of claim 10, further comprising a dielectric reflective layer on the active LED structure, wherein one or more portions of the metal reflective layer extend through the dielectric reflective layer to electrically couple the metal reflective layer to the active LED structure, wherein a portion of the dielectric reflective layer extends outside the sidewalls to contact the landing pad.

13. The LED chip of claim 12, wherein the one or more top passivation layers contact a portion of the dielectric reflective layer between the sidewalls and the landing pad.

14. A method of forming a light-emitting diode (LED) chip, the method comprising:
forming an active LED structure, the active LED structure comprising an n-type layer, a p-type layer, and an active layer between the n-type layer and the p-type layer, the active LED structure forming sidewalls that define a perimeter of the active LED structure;
depositing a dielectric reflective layer on the active LED structure, a portion of the dielectric reflective layer extending outside the sidewalls;
removing portions of the dielectric reflective layer to form a first opening in the dielectric reflective layer outside the sidewalls;
depositing a landing pad in the first opening;
depositing a metal reflective layer on the dielectric reflective layer and the landing pad such that the landing pad is electrically coupled to the metal reflective layer outside the sidewalls;
bonding the active LED structure to a carrier submount such that the metal reflective layer is between the active LED structure and the carrier submount; and
forming a contact on the landing pad such that the landing pad is between the contact and the metal reflective layer.

15. The method of claim 14, further comprising removing portions of the dielectric reflective layer to form a plurality of second openings over the active LED structure.

16. The method of claim 15, wherein depositing the metal reflective layer further comprises filling the plurality of second openings with the metal reflective layer to form electrically conductive pathways to the active LED structure.

17. The method of claim 15, wherein at least a portion of the landing pad is between the contact and the metal reflective layer in a direction perpendicular to the carrier submount.

18. The method of claim 14, wherein a portion of the landing pad laterally extends on the dielectric reflective layer in a position that is between the dielectric reflective layer and the metal reflective layer.

19. The method of claim 14, further comprising forming one or more top passivation layers on the sidewalls of the active LED structure, on one or more portions of the contact, and on portions of the dielectric reflective layer between the sidewalls and the landing pad.

20. The method of claim 14, wherein the metal reflective layer comprises a thickness in a range from 0.2 microns (μm) to 1.5 μm.
